(19) United States
(12) Patent Application Publication
(10) Pub. No.: US 2022/0166189 A1
(43) Pub. Date: May 26, 2022

(54) DIRECTLY-MODULATED LASER DIODE WITH GSG COPLANAR ELECTRODES AND MANUFACTURING METHOD THEREOF

(71) Applicant: LuxNet Corporation, Taoyuan City (TW)

(72) Inventor: YU-LUN WU, Taoyuan City (TW)

(21) Appl. No.: 17/399,089

(22) Filed: Aug. 11, 2021

(30) Foreign Application Priority Data
Nov. 24, 2020 (TW) 109141084

(51) Int. Cl. H01S 5/042; H01S 5/0234

(52) U.S. Cl. CPC H01S 5/0427; H01S 5/04256; H01S 5/0234

(57) ABSTRACT

A directly-modulated laser diode with GSG coplanar electrodes comprises a semi-insulating semiconductor substrate, an N-type semiconductor layer, a light-emitting layer, a P-type semiconductor layer, an insulating layer of dielectric material, a P-type electrode, and two N-type electrodes. It is characterized in that the two N-type electrodes are disposed on the N-type semiconductor layer and connected to the top of insulating layer along the sidewall to form a coplanar surface, the P-type electrode and the two N-type electrodes are GSG (ground-signal-ground) coplanar electrodes. The disclosure uses a hybrid coplanar waveguide structure with a higher direct modulation speed, and can be integrated with flip chip technology. Therefore, the disclosure reduces the signal transmission loss caused by package wiring and reduces the thermal effect caused by the device itself, and significantly improves the high frequency and photoelectric characteristics at high temperature.

### CROSS REFERENCE TO RELATED APPLICATION

This application claims the benefits of Taiwan application Serial No. 109141084, filed on Nov. 24, 2020, the disclosures of which are incorporated by references herein in its entirety.

### TECHNICAL FIELD

The present invention relates to a laser diode device, in particular to a directly-modulated laser diode with GSG coplanar electrodes and manufacturing method thereof.

### BACKGROUND

In order to achieve higher differential gain, increase output power and achieve higher response frequency, it is generally achieved by changing material properties, quantum well structure and short waveguide, but the use of short waveguide will increase the difficulty of manufacturing and packaging.

Generally, in order to simplify the structure and reduce the cost, a microstrip line waveguide structure is used, but the microstrip line structure causes higher microwave loss.

### SUMMARY

The present invention uses the GSG (ground-signal-ground) coplanar electrodes to make a high-speed hybrid coplanar transmission line structure with a semi-insulating substrate, which can effectively reduce the parasitic effects caused by junction capacitance, wiring capacitance and series resistance. And, the present invention can reduce the microwave loss caused by signal transmission and reduce the influence caused by RC circuit and microwave reflection, thereby improving the microwave characteristics of the directly-modulated laser diode to achieve higher direct modulation speed. In addition, the electric field of the GSG coplanar electrode structure is more concentrated, and the electrical signal is easier to pass through the waveguide, which is better than the GS electrode structure. This hybrid coplanar waveguide (Hybrid CPW) structure also has a GS electrode design, so the package selectivity is high.

An objective of the present invention is to provide a directly-modulated laser diode with GSG coplanar electrodes and manufacturing method thereof. The disclosure uses a hybrid coplanar waveguide structure with a higher direct modulation speed, and can be integrated with flip chip technology. Therefore, the disclosure reduces the signal transmission loss caused by package wiring and reduces the thermal effect caused by the device itself, and significantly improves the high frequency and photoelectric characteristics at high temperature.

The present invention achieves the above-indicated objective by providing a directly-modulated laser diode with GSG coplanar electrodes including a semi-insulating semiconductor substrate, an N-type semiconductor layer, a light-emitting layer, a P-type semiconductor layer, an insulating layer of dielectric material, a P-type electrode, and two N-type electrodes. It is characterized in that the two N-type electrodes are disposed on the N-type semiconductor layer and connected to the top of insulating layer along the sidewall to form a coplanar surface, the P-type electrode and the two N-type electrodes are GSG (ground-signal-ground) coplanar electrodes.

Compared to a conventional directly-modulated laser diode, the present invention has several advantages:

1. The hybrid coplanar waveguide structure can improve the microwave characteristics of the high-speed directly-modulated laser diode to achieve higher direct modulation speed.
2. The electric field of the GSG coplanar electrode structure is more concentrated, and the electrical signal is easier to pass through the waveguide, which is better than the GS electrode structure of the microstrip line waveguide structure.
3. The integration of the GSG coplanar electrodes and flip chip technology can reduce the signal transmission loss caused by the package wiring and achieve a higher direct modulation speed.
4. The GSG coplanar electrodes are integrated with the flip chip technology, the electrode is directly bonded to the package circuit, and the heat in the light-emitting area does not need to be conducted through the metal wire and the semiconductor substrate to dissipate heat, and can be directly conducted to the insulated package circuit substrate. Since the metal is directly connected, the thermal path and thermal resistance are extremely small, which can greatly improve the thermal effect and high temperature characteristics of the laser device.

### BRIEF DESCRIPTION OF THE DRAWINGS

FIG. 1 is a top view schematic diagram of a directly-modulated laser diode with GSG coplanar electrodes of the present invention.

FIG. 2 is an A-A cross-sectional view of FIG. 1.

FIG. 3 is a B-B cross-sectional view of FIG. 1.

FIG. 4 is a schematic diagram of the flip-chip package of the directly-modulated laser diode with GSG coplanar electrodes in the A-A cross-sectional plane of FIG. 2.

FIG. 5 is a schematic diagram of the flip-chip package of the directly-modulated laser diode with GSG coplanar electrodes in the B-B cross-sectional plane of FIG. 3.

FIG. 6 is a schematic diagram of a signal to ground transmission of a directly-modulated laser diode with a hybrid coplanar waveguide structure.

FIG. 7 is a schematic diagram of a signal to ground transmission of a directly-modulated laser diode with a microstrip line waveguide structure.

FIG. 8 is a schematic diagram of metal wire packaging.

FIG. 9 is a schematic diagram of flip chip packaging.

FIG. 10 is a flowchart of a method for manufacturing a directly-modulated laser diode with GSG coplanar electrodes of the present invention.

### DETAILED DESCRIPTION

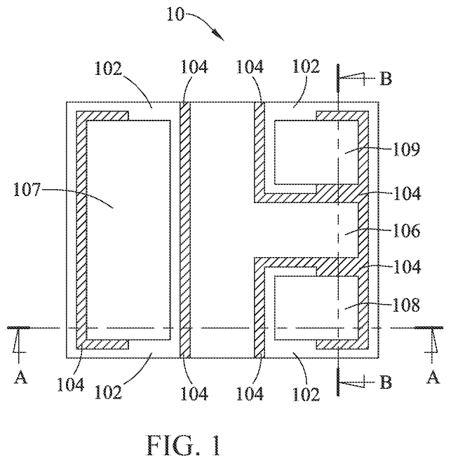

FIG. 1 is a top view schematic diagram of a directly-modulated laser diode with GSG coplanar electrodes of the present invention. As shown in FIG. 1, a directly-modulated laser diode 10 has an N-type semiconductor layer 102, an insulating layer of dielectric material 104, a P-type electrode 106, an N-type electrode 107, an N-type electrode 108 and an N-type electrode 109.

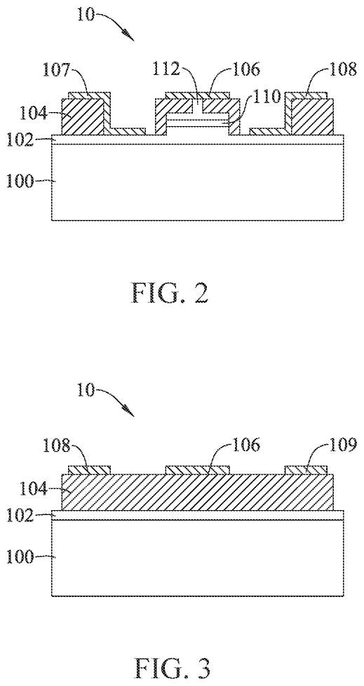

FIG. 2 is an A-A cross-sectional view of FIG. 1, and FIG. 3 is a B-B cross-sectional view of FIG. 1. The directly-modulated laser diode 10 also has a semi-insulating semiconductor substrate 100, a light emitting layer 110 and a P-type semiconductor layer 112. A structure of the directly-modulated laser diode with GSG coplanar electrodes is shown in FIG. 2. After the waveguide structure manufacturing process is completed, the pattern of insulating layer is defined and completed. Finally, P type and N type metal electrodes are formed on the device. The N-type electrodes 107, 108 and 109 are disposed on the N-type semiconductor layer 102 and connected to the top of insulating layer 104 along the sidewall to form a coplanar surface. It can be seen from FIG. 3 that the P-type electrode 106, the N-type electrode 108 and the N-type electrode 109 are GSG (ground-signal-ground) coplanar electrodes.

The directly-modulated laser diode with GSG coplanar electrodes of the present invention is suitable for the integration of flip chip packaging technology. The directly-modulated laser diode 10 can be directly connected to a circuit substrate required for packaging, such as a common SOI (Silicon On Insulator) substrate or an AlN (aluminum nitride) substrate and many other types of insulating substrates.

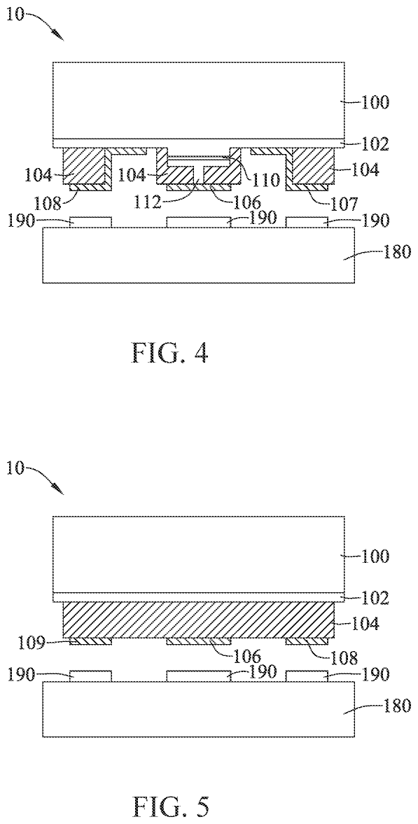

FIG. 4 is a schematic diagram of the flip-chip package of the directly-modulated laser diode with GSG coplanar electrodes in the A-A cross-sectional plane of FIG. 2. FIG. 5 is a schematic diagram of the flip-chip package of the directly-modulated laser diode with GSG coplanar electrodes in the B-B cross-sectional plane of FIG. 3. After the directly-modulated laser diode with GSG coplanar electrodes 10 is inverted and aligned, it is directly bonded to the package substrate (flip chip bonding). As shown in FIG. 4 and FIG. 5, the P-type electrode 106 and the N-type electrodes 107, 108 and 109 of the GSG coplanar electrodes are bonded with the eutectic metal 190 in the insulated package circuit substrate 180 to complete the flip chip packaging process.

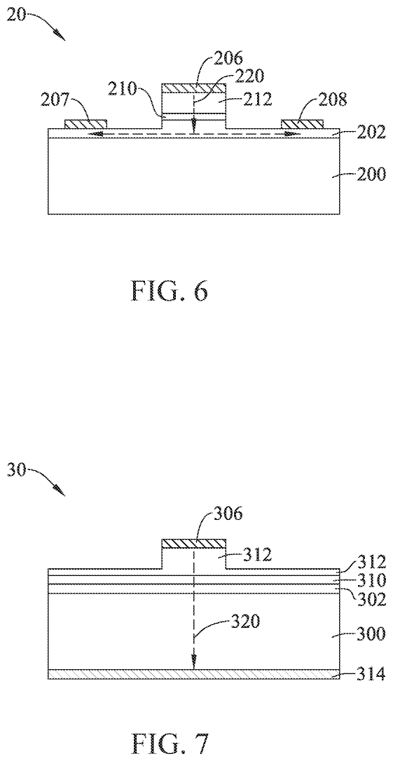

FIG. 6 is a schematic diagram of a signal to ground transmission of a directly-modulated laser diode with a hybrid coplanar waveguide structure. As shown in FIG. 6, a directly-modulated laser diode 20 has a semi-insulating semiconductor substrate 200, an N-type semiconductor layer 202, a light emitting layer 210, a P-type semiconductor layer 212, a P-type electrode 206, an N-type electrode 207 and an N-type electrode 208. Among them, there is a signal to ground transmission path 220 of the laser diode of the hybrid coplanar waveguide structure. FIG. 7 is a schematic diagram of a signal to ground transmission of a directly-modulated laser diode with a microstrip line waveguide structure. As shown in FIG. 7, a directly-modulated laser diode 30 has an N-type electrode 314, a semiconductor substrate 300, an N-type semiconductor layer 302, a light emitting layer 310, a P-type semiconductor layer 312 and a P-type electrode 306. Among them, there is a signal to ground transmission path 320 of the laser diode with a microstrip line waveguide structure.

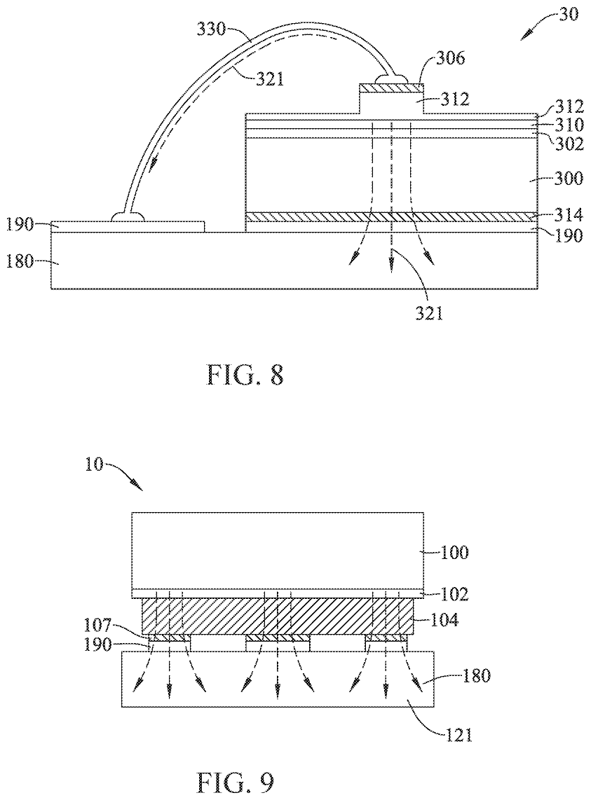

FIG. 8 is a schematic diagram of metal wire packaging. Generally, a common low-cost manufacturing process uses a metal wire package type, but when a signal is transmitted through the metal wire 330, the long transmission distance and the capacitance and inductance effect will cause additional transmission loss. FIG. 9 is a schematic diagram of flip chip packaging. The directly-modulated laser diode with GSG coplanar electrodes of the present invention is suitable for the flip-chip packaging process, the GSG coplanar electrodes are directly bonded to the packaging circuit, and the signal is directly transmitted by the metal circuit, which greatly reduces the signal transmission loss.

As shown in FIG. 8, because the light-emitting area of the directly-modulated laser diode 30 produces extremely high thermal effects during operation, the common non-coplanar structures such as microstrip line uses metal wires 330 or semiconductor substrate 300 to dissipate heat. The thermal conduction path 321 is relatively long and has a large thermal resistance, and the poor heat dissipation effect causes severe thermal effects to affect the characteristics of the laser device. As shown in FIG. 9, the GSG coplanar electrodes of the directly-modulated laser diode 10 are directly bonded to the package circuit. The heat energy in the light-emitting area does not need to be conducted through the metal wire and the semiconductor substrate to dissipate heat, and can be directly conducted to the insulated package circuit substrate 180 (usually a material with good heat dissipation characteristics) through a thermal conduction path 121. Since the metal is directly connected, the thermal path and thermal resistance are extremely small, which can greatly improve the thermal effects and high temperature characteristics of the laser device.

The directly-modulated laser diode adopts a hybrid coplanar waveguide structure, and the signal to ground (S to G or P to N) is no longer transmitted through the semiconductor substrate (micrometer thickness) but directly transmitted through the top N-type semiconductor layer (nanometer thickness), it effectively reduces the signal transmission loss caused by the RC circuit. Comparing the signal to ground transmission path 220 of the directly-modulated laser diode with a hybrid coplanar waveguide structure shown in FIG. 6 and the signal to ground transmission path 320 of the directly-modulated laser diode with a microstrip line waveguide structure shown in FIG. 7, it can be seen that the hybrid coplanar waveguide structure can improve the microwave characteristics of the high-speed directly-modulated laser diode to achieve higher direct modulation speed. In addition, the electric field of the GSG coplanar electrode structure is more concentrated, and the electrical signal is easier to pass through the waveguide, which is better than the GS electrode structure of the microstrip line waveguide structure.

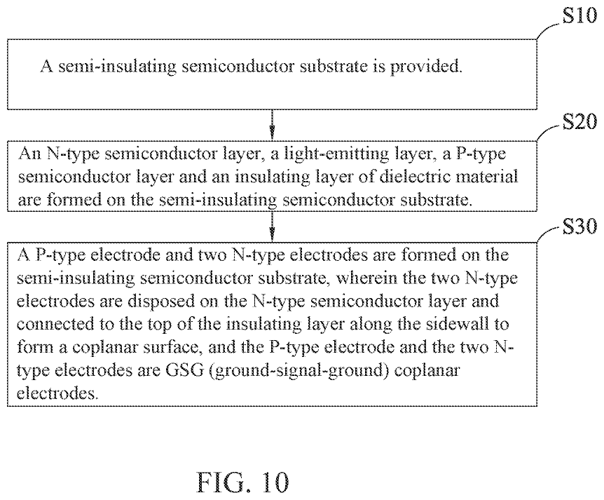

FIG. 10 is a flowchart of a method for manufacturing a directly-modulated laser diode with GSG coplanar electrodes of the present invention. First, as shown in FIG. 10, a semi-insulating semiconductor substrate is provided as shown in step S10. Next, an N-type semiconductor layer, a light-emitting layer, a P-type semiconductor layer and an insulating layer of dielectric material are formed on the semi-insulating semiconductor substrate as shown in step S20. Finally, a P-type electrode and two N-type electrodes are formed on the semi-insulating semiconductor substrate, wherein the two N-type electrodes are disposed on the N-type semiconductor layer and connected to the top of the insulating layer along the sidewall to form a coplanar surface, and the P-type electrode and the two N-type electrodes are GSG (ground-signal-ground) coplanar electrodes as shown in step S30.

What is claimed is:

1. A directly-modulated laser diode with GSG coplanar electrodes, comprising:
a semi-insulating semiconductor substrate, an N-type semiconductor layer, a light-emitting layer, a P-type semiconductor layer, an insulating layer of dielectric material, a P-type electrode and two N-type electrodes;
characterized in that the two N-type electrodes are disposed on the N-type semiconductor layer and connected to the top of insulating layer along the sidewall to form a coplanar surface, the P-type electrode and the two N-type electrodes are GSG (ground-signal-ground) coplanar electrodes.

2. The directly-modulated laser diode with GSG coplanar electrodes as recited in claim 1, wherein the directly-modulated laser diode with GSG coplanar electrodes can be connected with SOI (Silicon On Insulator) substrate or AlN (aluminum nitride) circuit substrate for flip chip packaging.

3. The directly-modulated laser diode with GSG coplanar electrodes as recited in claim 1, wherein a signal to ground transmission of the directly-modulated laser diode with GSG coplanar electrodes is directly transmitted through the N-type semiconductor layer.

4. A method for manufacturing a directly-modulated laser diode with GSG coplanar electrodes, comprising the steps of:
providing a semi-insulating semiconductor substrate;
forming an N-type semiconductor layer, a light-emitting layer, a P-type semiconductor layer and an insulating layer of dielectric material on the semi-insulating semiconductor substrate; and
forming a P-type electrode and two N-type electrodes on the semi-insulating semiconductor substrate;
characterized in that the two N-type electrodes are disposed on the N-type semiconductor layer and connected to the top of insulating layer along the sidewall to form a coplanar surface, the P-type electrode and the two N-type electrodes are GSG (ground-signal-ground) coplanar electrodes.

5. The method for manufacturing a directly-modulated laser diode with GSG coplanar electrodes as recited in claim 4, wherein the directly-modulated laser diode with GSG coplanar electrodes can be connected with SOI (Silicon On Insulator) substrate or AlN (aluminum nitride) circuit substrate for flip chip packaging.

6. The method for manufacturing a directly-modulated laser diode with GSG coplanar electrodes as recited in claim 4, wherein a signal to ground transmission of the directly-modulated laser diode with GSG coplanar electrodes is directly transmitted through the N-type semiconductor layer.
